(19) United States
(12) Patent Application Publication
(10) Pub. No.: US 2008/0042693 A1
(43) Pub. Date: Feb. 21, 2008

(54) DESIGN STRUCTURES COMPRISING RECEIVER CIRCUITS FOR GENERATING DIGITAL CLOCK SIGNALS

(76) Inventors: William L. Bucossi, Burlington, VT (US); Hongfei Wu, Colchester, VT (US)

Correspondence Address: SCHMEISER, OLSEN & WATTS, 22 CENTURY HILL DRIVE, SUITE 302, LATHAM, NY, 12110, US

(21) Appl. No.: 11/847,406

(22) Filed: Aug. 30, 2007

Related U.S. Application Data
(63) Continuation-in-part of application No. 11/275,537, filed on Jan. 12, 2006, now Pat. No. 7,295,044.

(51) Int. Cl. H03K 5/24

(52) U.S. Cl. 327/65

(57) ABSTRACT

A design structure comprising a digital clock generation circuit (and a method for operating the same). The digital clock generation circuit includes a first, a second, a third differential comparator circuits. The first differential comparator circuit receives the positive differential clock signal and a reference voltage, and generates a first output signal. The second differential comparator circuit receives the positive and negative differential clock signal, and generates a second output signal. The third differential comparator circuit receives the reference voltage and the negative differential clock signal, and generates a third output signal. A bus change-over detecting circuit receives the first output signal, and the third output signal, and generates an Enable signal. The digital clock generation circuit further includes a latch circuit which receives the second output signal, and the Enable signal and generates a digital clock signal. The latch circuit comprises a latch with glitch or noise immunity.

### CROSS-REFERENCE TO RELATED APPLICATIONS

The present U.S. utility patent application is a continuation in part of U.S. patent application Ser. No. 11/275,537 titled, “Receiver Circuits For Generating Digital Clock Signals”, filed Jan. 12, 2006 and is assigned to the present Assignee.

### FIELD OF THE INVENTION

The present invention relates to design structures comprising digital clock generation circuits, and more specifically, to design structures comprising circuit for generating a digital clock signal from a Differential Comparator Circuit which correctly handles a special case called the “high-high” condition

### BACKGROUND OF THE INVENTION

On a Front Side Bus, there are receiving circuits that convert small signal differential clock signals to a digital clock signal to be used on-chip. The inputs to these circuits are called the Strobe and StrobeN. A condition exists when a transmitting device stops driving the Front Side Bus (called bus change-over) and both Strobe and StrobeN signals are at logic ‘1’. During this condition, it is advantageous for the on-chip digital clock signal to remain in a well defined logic state despite the state of the signals coming in from the bus. Therefore, there is a need for a clock generation circuit (and a method for operating the same) in which the digital clock signal can be controlled to stay at a defined logic state.

### SUMMARY OF THE INVENTION

The present invention provides a design structure including a clock generation circuit, comprising (a) a first differential comparator circuit, wherein the first differential comparator circuit receives as input (i) a first differential clock signal and (ii) a reference voltage, and generates a first output signal; (b) a second differential comparator circuit, wherein the second differential comparator circuit receives as input (i) the first differential clock signal and (ii) a second differential clock signal, and generates a second output signal, wherein in response to the first and the second differential clock signals switching, the second differential comparator circuit is capable of causing the second output signal to switch logic states; (c) a third differential comparator circuit, wherein the third differential comparator circuit receives as input (i) the reference voltage and (ii) the second differential clock signal, and generates a third output signal; (d) a bus change-over detecting circuit, wherein the bus change-over detecting circuit receives as input (i) the first output signal, and (ii) the third output signal, and generates an Enable signal; and (e) a latch circuit, wherein the latch circuit receives as input (i) the second output signal, and (ii) the Enable signal, wherein the latch circuit generates a digital clock signal, and wherein the latch circuit comprises a latch.

The present invention provides a design structure including a circuit for a clock generation method, comprising providing a clock generation circuit which includes (a) a first differential comparator circuit, wherein the first differential comparator circuit receives as input (i) a first differential clock signal and (ii) a reference voltage, and generates a first output signal, (b) a second differential comparator circuit, wherein the second differential comparator circuit receives as input (i) the first differential clock signal and (ii) a second differential clock signal, and generates a second output signal, (c) a third differential comparator circuit, wherein the third differential comparator circuit receives as input (i) the reference voltage and (ii) the second differential clock signal, and generates a third output signal, (d) a bus change-over detecting circuit, wherein the bus change-over detecting circuit receives as input (i) the first output signal, and (ii) the third output signal, and generates an Enable signal, and (e) a latch circuit, wherein the latch circuit receives as input (i) the second output signal, and (ii) the Enable signal, wherein the latch circuit generates a digital clock signal, and wherein the latch circuit comprises a latch; and in response to the first and the second differential clock signals switching, using the second differential comparator circuit to cause the second output signal to switch logic states.

The present invention provides a design structure including a clock generation circuit, comprising (a) a first differential comparator circuit, wherein the first differential comparator circuit receives as input (i) a first differential clock signal and (ii) a reference voltage, and generates a first output signal; (b) a second differential comparator circuit, wherein the second differential comparator circuit receives as input (i) the first differential clock signal and (ii) a second differential clock signal, and generates a second output signal, wherein in response to the first and the second differential clock signals switching, the second differential comparator circuit is capable of causing the second output signal to switch logic states; (c) a third differential comparator circuit, wherein the third differential comparator circuit receives as input (i) the reference voltage and (ii) the second differential clock signal, and generates a third output signal; (d) a bus change-over detecting circuit, wherein the bus change-over detecting circuit receives as input (i) the first output signal, and (ii) the third output signal, and generates an Enable signal; and (e) a latch circuit, wherein the latch circuit receives as input (i) the second output signal, and (ii) the Enable signal, wherein the latch circuit generates a digital clock signal, and wherein the latch circuit comprises a latch, wherein in response to the first and second differential clock signals not being both higher than the reference voltage, the bus change-over detecting circuit is capable of adjusting the Enable signal resulting in the second output signal passing unchanged through the latch circuit as the digital clock signal, and wherein in response to both the first and second differential clock signals being higher than the reference voltage, the latch circuit is capable of holding the digital clock signal at a previous state.

The present invention provides a design structure including a digital clock generation circuit that can maintain a well defined logic state during the high-high condition.

### BRIEF DESCRIPTION OF THE DRAWINGS

FIG. 1 illustrates a design structure comprising a Front Side Bus (FSB), in accordance with embodiments of the present invention.

FIG. 2 illustrates a detail configuration of a design structure comprising a device connected to a FSB (of FIG. 1), in accordance with embodiments of the present invention.

FIG. 3 illustrates the wave forms of the three signals Strobe, StrobeN, and digital clock signal depicting the problem solved by the present invention

FIG. 4 illustrates a detail configuration of a design structure comprising a receiver circuit of FIG. 2, in accordance with embodiments of the present invention.

FIG. 5 illustrates a detail configuration of a design structure comprising a latch circuit of FIG. 3, in accordance with embodiments of the present invention.

FIG. 6 illustrates the wave forms of the three signals Strobe, StrobeN, and the digital clock signal of FIGS. 2, 4, and 5 in a second embodiment of the present invention.

FIG. 7 shows a diagram of an exemplary design flow process in which the design structure of the present invention is processed into a form useful for developing and manufacturing clock generation circuits.

### DETAILED DESCRIPTION OF THE INVENTION

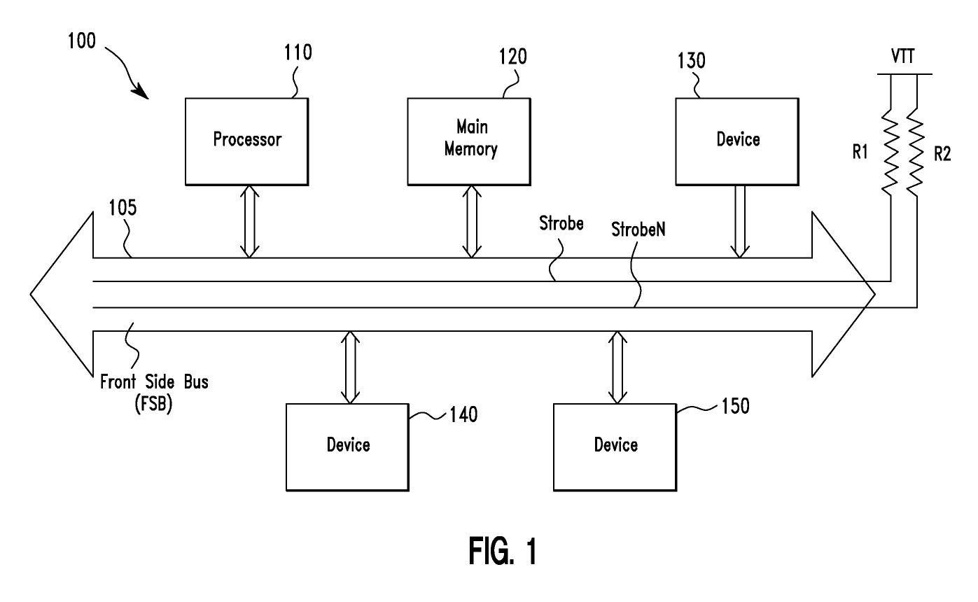

FIG. 1 illustrates a design structure for a FSB 100, in accordance with embodiments of the present invention. More specifically, in one embodiment, the FSB 100 comprises a processor 110, a main memory 120, and some devices 130, 140, and 150, all of which are electrically connected together via an FSB (Front Side Bus) 105. In one embodiment, the FSB 105 comprises two lines Strobe and StrobeN which are electrically connected to a termination voltage VTT via two termination resistors R1 and R2, respectively. The two lines Strobe and StrobeN carry a differential clock signal. The two signals Strobe and StrobeN are used to synchronize the transfer of data from a transmitting device of the digital system 100 (e.g., device 130) to one or more receiving device of the digital system 100 (e.g., device 140). It should be noted that, at one time, the device 130 can be a transmitting device and the device 140 can be a receiving device, but at another time, the device 130 can be a receiving device and the device 140 can be a transmitting device.

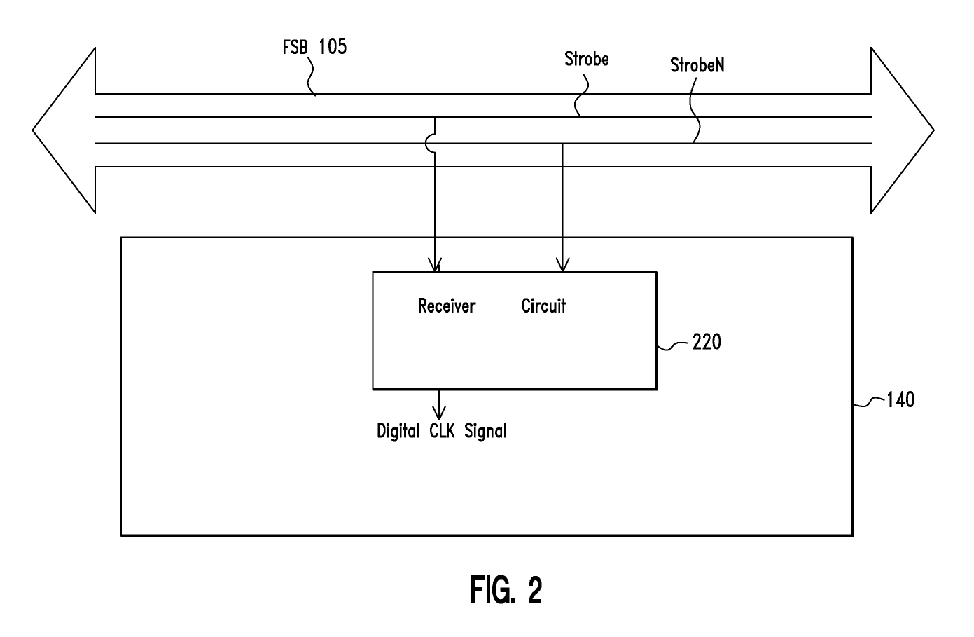

FIG. 2 illustrates a detail configuration of a design structure for the device 140 of FIG. 1, in accordance with embodiments of the present invention. In one embodiment, the device 140 comprises a receiver circuit 220 which is electrically connected to the two lines Strobe and StrobeN of the FSB 105. With reference FIG. 1 and FIG. 2, as an example, assume that, at a point of time, the device 140 is receiving data from the device 130 (FIG. 1). In one embodiment, the receiving circuit 220 of the device 140 receives the two signals Strobe and StrobeN from the device 130 via the two lines Strobe and StrobeN of the FSB 105, respectively, and converts the two signals Strobe and StrobeN into a digital clock signal. The digital clock signal is used to synchronize the transfer of data from the transmitting device 130 to the receiving device 140.

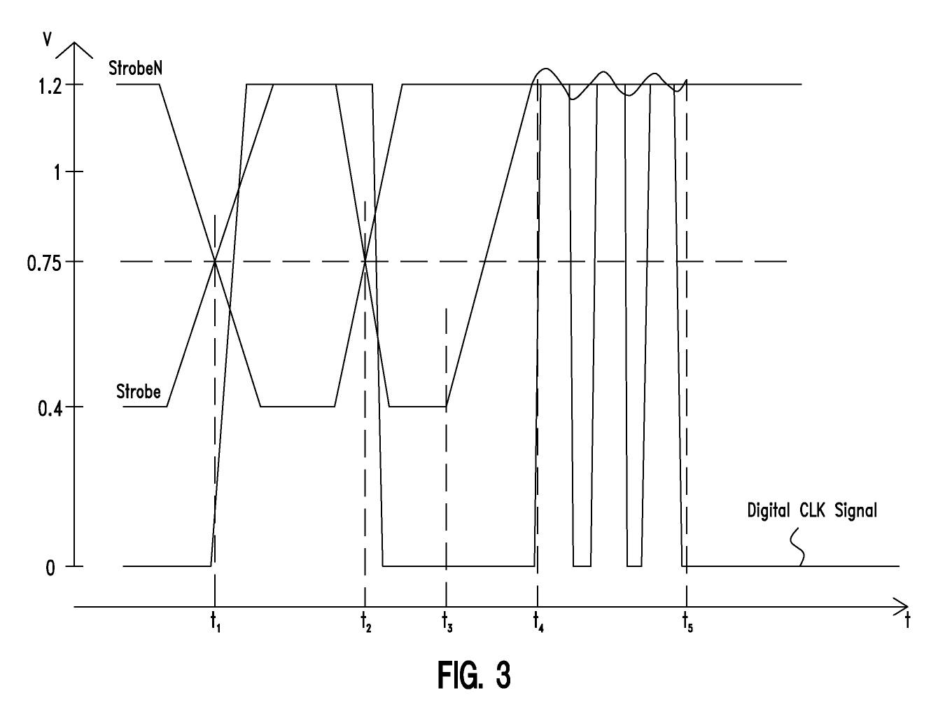

FIG. 3 illustrates the wave forms of the three signals Strobe, StrobeN, and digital clock signal in a first embodiment of the present invention. In one embodiment, the digital clock signal switches logic states whenever the difference (in voltage level) between the signal StrobeN and the signal Strobe changes signs. Assume that, in one embodiment, before time t1, when the sign of the difference (in voltage level) between the signal StrobeN and the signal Strobe is positive, the digital clock signal is at logic 0. In one embodiment, at time t1, the two signals Strobe and StrobeN switch; therefore, from time t1 to time t2, the difference (in voltage level) between the signal StrobeN and the signal Strobe changes from positive to negative. As a result, the digital clock signal changes from logic 0 to logic 1 (1.2V). In one embodiment, at time t2, the two signals Strobe and StrobeN switch again; therefore, from time t2 to time t3, the difference (in voltage level) between the signal StrobeN and the signal Strobe changes from negative to positive. As a result, the digital clock signal changes from logic 1 to logic 0. In one embodiment, at time t3, assume that the transmitting device 130 of FIG. 1 stops driving the FSB 105 (called bus change-over). As a result, from time t3 to time t4, the signal StrobeN stays at 1.2V and the signal Strobe rises from 0.4V toward VCC (1.2V) (because both the two signals Strobe and StrobeN terminate at VTT). Therefore, during this time period (i.e., from time t3 to time t4), the difference (in voltage level) between the signal Strobe and the signal StrobeN remain at positive. As a result, the digital clock signal remains at logic 0. In one embodiment, from the time t4 to time t5, the signal StrobeN stays at 1.2V and the signal Strobe oscillates around 1.2V. As a result, the digital clock signal oscillates between logic 0 and logic 1. In one embodiment, after time t5, when the two signals Strobe and StrobeN stay at 1.2V, the digital clock signal stays at logic 0.

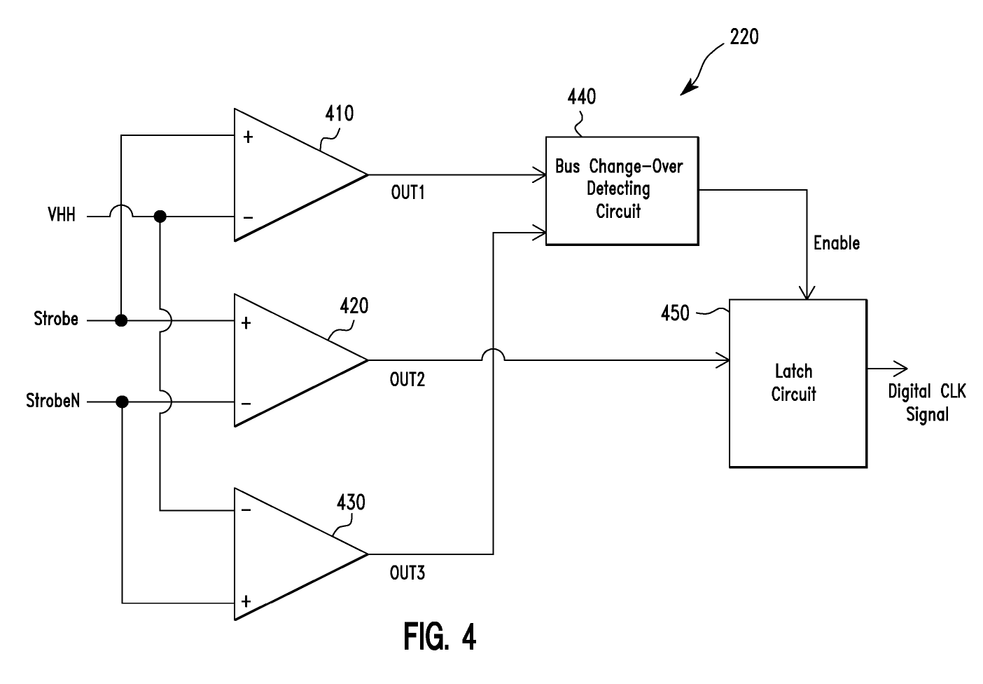

FIG. 4 illustrates a detail configuration of a design structure for the receiver circuit 220 of FIG. 2, in accordance with embodiments of the present invention. More specifically, the receiver circuit 220 comprises three differential comparators 410, 420, and 430, a bus change-over detecting circuit 440, and a latch circuit 450. More specifically, in one embodiment, the differential comparator 410 receives as inputs the signal Strobe and a reference voltage VHH and generates a signal OUT1. In one embodiment, the voltage level of the reference voltage VHH is 1V. In one embodiment, the differential comparator 420 receives as inputs the two signals Strobe and StrobeN and generates a signal OUT2 whereas the differential comparator 430 receives as inputs the two signals StrobeN and the reference voltage VHH and generates a signal OUT3. In one embodiment, the bus change-over detecting circuit 440 receives as inputs the two signals OUT1 and OUT3 and generates a signal Enable to the latch circuit 450. In one embodiment, the latch circuit 450 receives as input the signal OUT2 and generates the digital clock signal. The latch circuit 450 also receives the signal Enable from the bus change-over detecting circuit 440.

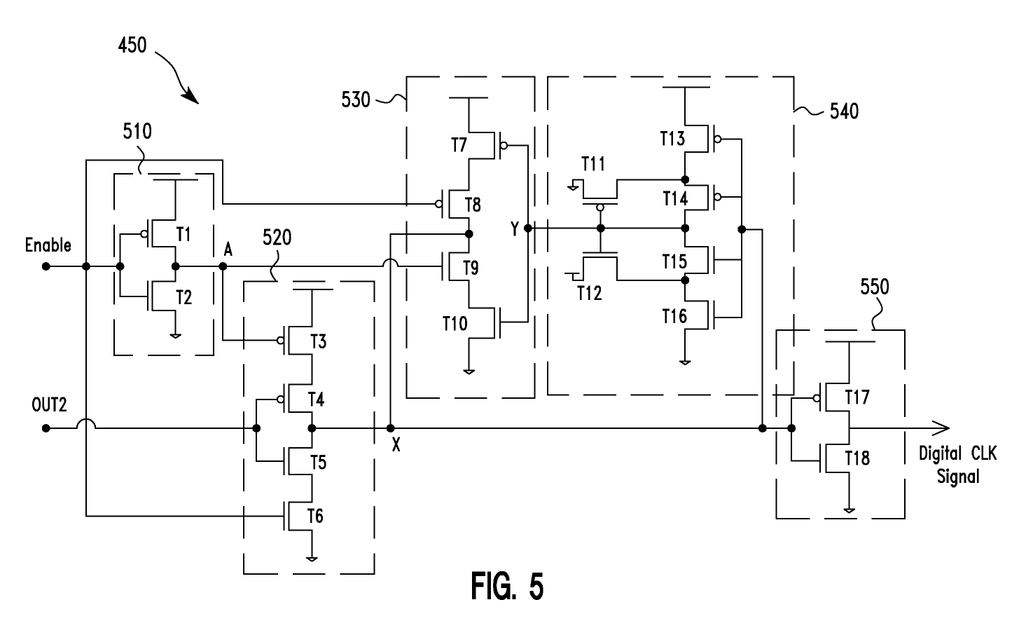

FIG. 5 illustrates a detail configuration of a design structure for the latch circuit 450 of FIG. 3, in accordance with embodiments of the present invention. More specifically, the latch circuit 450 comprises four inverters 510, 520, 530, and 550 and a Glitch Immunity circuit 540. It should be noted that the Glitch Immunity circuit 540 is also an inverter. The two inverters 530 and 540 are cross connected and therefore they form a latch (hence the name the latch circuit 450).

In one embodiment, the inverter 510 comprises a p-channel transistor T1 and an n-channel transistor T2 electrically connected in series between Vcc and Ground. In one embodiment, the inverter 520 comprises two p-channel transistors T3 and T4 and two n-channel transistors T5 and T6. Illustratively, four transistors T3, T4, T5 and T6 are electrically connected in series between Vcc and Ground. In one embodiment, the inverter 530 comprises two p-channel transistors T7 and T8 and two n-channel transistors T9 and T10. Illustratively, four transistors T7, T8, T9 and T10 are electrically connected in series between Vcc and Ground. In one embodiment, the inverter 550 comprises a p-channel transistor T17 and an n-channel transistor T18. Illustratively, two transistors T17 and T18 are electrically connected in series between Vcc and Ground. In one embodiment, the Glitch Immunity 540 comprises three p-channel transistors T11, T13, and T14, and three n-channel transistors T12, T15 and T16. Illustratively, four transistors T13, T14, T15 and T16 are electrically connected in series between Vcc and Ground.

In one embodiment, the inverter 510 receives as input the Enable signal and sends a first digital signal to node A. The inverter 520 receives as input the signal OUT2 and sends a second digital signal to node X. The transistor T3 receives the first digital signal from node A. The Glitch Immunity 540 receives as input the second digital signal from node X and sends a third digital signal to node Y. The inverter 530 receives as input the third digital signal from node Y and sends the second digital signal to node X. The transistor T8 receives as input the Enable signal. The inverter 550 receives as input the second digital signal and generates the digital clock signal.

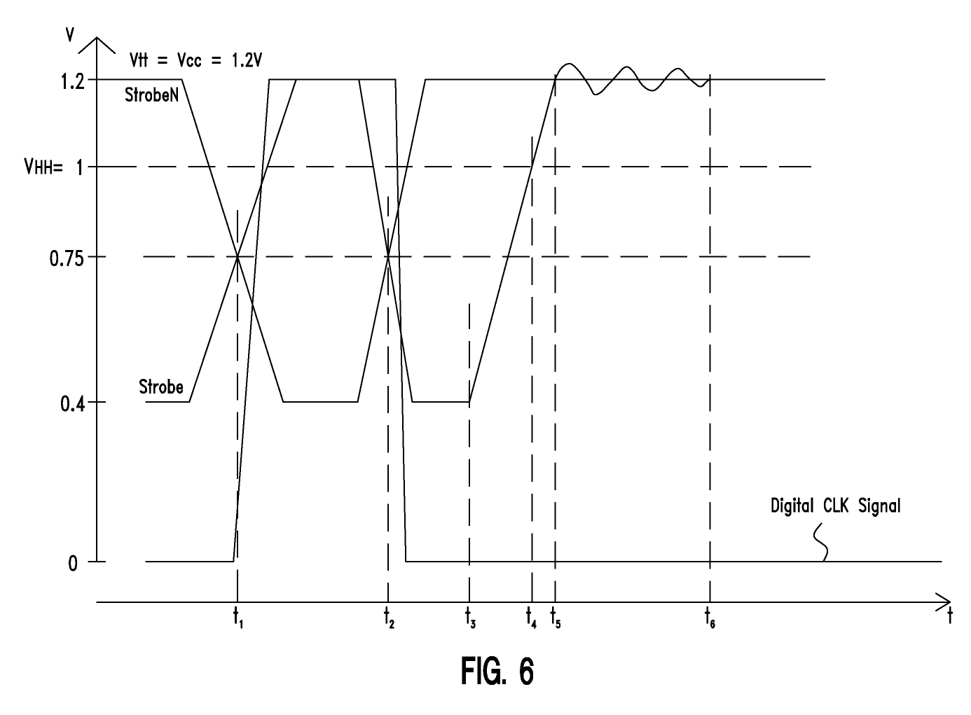

FIG. 6 illustrates the wave forms of the three signals Strobe, StrobeN, and the digital clock signal of FIGS. 2, 4, and 5 in a second embodiment of the present invention, in which the transmitting device 130 of the digital system 100 of FIG. 1 is sending data to the receiving device 140 of the digital system 100.

In one embodiment, the operation of the bus change-over detecting circuit 440 of the FIG. 4 is as follows. Only in case of both the two signals OUT1 and OUT3 being at logic 1, the bus change-over detecting circuit 440 generates the Enable signal at logic 0. Otherwise, the bus change-over detecting circuit 440 generates the Enable signal at logic 1. In one embodiment, the bus change-over detecting circuit 440 is a NAND gate. As can be seen in FIG. 6, before time t4, the two signals Strobe and StrobeN are not both higher (in voltage level) than VHH. Therefore, the two signals OUT1 and OUT3 are not both at logic 1. As a result, the bus change-over detecting circuit 440 generates the Enable signal at logic 1. After time t4, both the two signals Strobe and StrobeN are higher (in voltage level) than VHH. Therefore, both the two signals OUT1 and OUT3 are at logic 1, and as a result, the bus change-over detecting circuit 440 generates the Enable signal at logic 0.

With reference to FIGS. 2, 4, 5 and 6, in one embodiment, the operation of the receiver circuit 220 is as follows. As can be seen in FIG. 6, before time t1, the signal StrobeN is higher (in voltage level) than the signal Strobe. As a result, the signal OUT2 of the differential comparator 420 of FIG. 4 is at logic 0. During this time period (i.e., before time t1), the Enable signal is at logic 1. As a result, the latch circuit 450 of FIG. 4 allows the signal OUT2 to pass through it unchanged. Therefore, the digital clock signal is the same of the OUT2 signal. More specifically, the inverter 520 of the latch circuit 450 inverts the digital signal OUT2 into the second digital signal at node X and then the inverter 550 the latch circuit 450 inverts the second digital signal at node X to the digital clock signal. In other words, the digital clock signal is the same of the OUT2 signal, which is at logic 0.

In one embodiment, as can be seen in FIG. 6, from time t1 to time t2, the signal StrobeN is lower (in voltage level) than the signal Strobe. As a result, the signal OUT2 of the differential comparator 420 of FIG. 4 is at logic 1. During this time period (e.g., before time t4), the Enable signal is at logic 1. As a result, the latch circuit 450 of FIG. 4 allows the signal OUT2 to pass through it unchanged. Therefore, the digital clock signal is the same of the OUT2 signal. More specifically, the inverter 520 of the latch circuit 450 inverts the digital signal OUT2 into the second digital signal at node X and then the inverter 550 the latch circuit 450 inverts the second digital signal at node X to the digital clock signal. In other words, the digital clock signal is the same of the OUT2 signal, which is at logic 1.

In one embodiment, as can be seen in FIG. 6, from time t2 to time t3, the signal StrobeN is higher (in voltage level) than the signal Strobe. As a result, the signal OUT2 of the differential comparator 420 of FIG. 4 is at logic 0. During this time period (e.g., before time t4), the Enable signal is at logic 1. As a result, the latch circuit 450 of FIG. 4 allows the signal OUT2 to pass through it unchanged. Therefore, the digital clock signal is the same of the OUT2 signal. More specifically, the inverter 520 of the latch circuit 450 inverts the digital signal OUT2 into the second digital signal at node X and then the inverter 550 the latch circuit 450 inverts the second digital signal at node X to the digital clock signal. In other words, the digital clock signal is the same of the OUT2 signal, which is at logic 0.

In one embodiment, as can be seen in FIG. 6, at time t3, the transmitting device 130 stops driving the FSB 105. As a result, the signal StrobeN stays at VTT and the signal Strobe rises from 0.4V toward VTT. From time t3 to time t4, the signal StrobeN is higher (in voltage level) than the signal Strobe. As a result, the signal OUT2 of the differential comparator 420 is at logic 0. During this time period (from time t3 to time t4, which is before time t4), the Enable signal is at logic 1. As a result, the latch circuit 450 of FIG. 4 allows the signal OUT2 to pass through it unchanged. More specifically, the inverter 520 of the latch circuit 450 inverts the digital signal OUT2 into the digital signal at node X and then the inverter 550 the latch circuit 450 inverts the digital signal at node X to the digital clock signal. In other words, the digital clock signal is the same of the OUT2 signal, which is at logic 0.

In one embodiment, as can be seen in FIG. 6, after time t4, the bus change-over detecting circuit 440 of the FIG. 4 generates the Enable signal at logic 0. As a result, the latch circuit 450 of FIG. 4 is in a hold mode. In other words, the latch circuit 450 holds the digital clock signal at the logic state at the time when the latch circuit 450 enters the hold mode. It should be noted that, due to the delay of the bus change-over detecting circuit 440, the latch circuit 450 may enter the hold mode sometime after time t5. This means that, after time t5, the oscillation of signal OUT2, caused by the signal Strobe oscillating around VTT, may arrive at the latch circuit 450 before the latch circuit 450 enters the hold mode. Even so, the Glitch Immunity circuit 540 prevents the digital signal at node X from oscillating in response to the oscillation of the signal OUT2. As a result, after time t5, when the latch circuit 450 enters the hold mode the digital clock signal is unchanged (i.e., stays at logic 0).

In one embodiment, the operation of the Glitch Immunity circuit 540 is as follows (Schmitt Trigger Functionality). Suppose initially, node X=‘0’ and node Y=‘1’. As node X begins to transition from ‘0’ to ‘1’, transistors T15/T16 start to turn on and transistors T13/T14 start to turn off. T12 is on because Y=‘1’ so T12 tries to hold node Y at logic 1 contending with transistors T15/T16 which are trying to pull node Y to ‘logic 0. Eventually, when node X rises high enough that transistors T15/T16 over-power T12, node Y transitions to logic 0. The same operation holds for the falling edge of node X but transistors T13/T14 and T11 come into play.

In comparison between the second embodiment of the present invention (FIG. 6) and the first second embodiment of the present invention (FIG. 3), it can be seen that, in the second embodiment, after the transmitting device 130 stops driving the FSB 105 (i.e., after time t3), there is no oscillation in the digital clock signal.

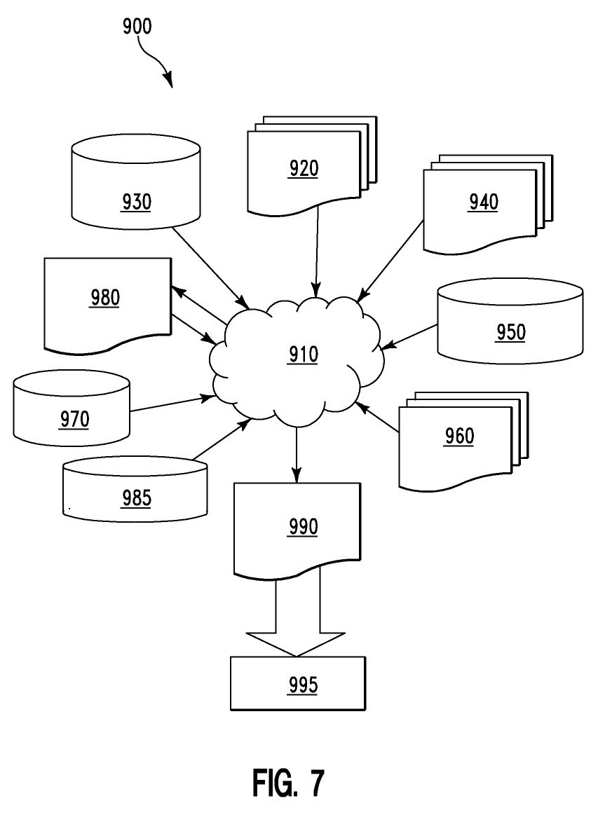

FIG. 7 shows a block diagram of an example design flow 900. Design flow 900 may vary depending on the type of IC being designed. For example, a design flow 900 for building an application specific IC (ASIC) may differ from a design flow 900 for designing a standard component. Design structure 920 is preferably an input to a design process 910 and may come from an IP provider, a core developer, or other design company or may be generated by the operator of the design flow, or from other sources. Design structure 920 comprises circuit 100 in the form of schematics or HDL, a hardware-description language (e.g., Verilog, VHDL, C, etc.). Design structure 920 may be contained on one or more machine readable medium. For example, design structure 920 may be a text file or a graphical representation of circuit 100. Design process 910 preferably synthesizes (or translates) circuit 100 into a netlist 980, where netlist 980 is, for example, a list of wires, transistors, logic gates, control circuits, I/O, models, etc. that describes the connections to other elements and circuits in an integrated circuit design and recorded on at least one of machine readable medium. This may be an iterative process in which netlist 980 is resynthesized one or more times depending on design specifications and parameters for the circuit.

Design process 910 may include using a variety of inputs; for example, inputs from library elements 930 which may house a set of commonly used elements, circuits, and devices, including models, layouts, and symbolic representations, for a given manufacturing technology (e.g., different technology nodes, 32 nm, 45 nm, 90 nm, etc.), design specifications 940, characterization data 950, verification data 960, design rules 970, and test data files 985 (which may include test patterns and other testing information). Design process 910 may further include, for example, standard circuit design processes such as timing analysis, verification, design rule checking, place and route operations, etc. One of ordinary skill in the art of integrated circuit design can appreciate the extent of possible electronic design automation tools and applications used in design process 910 without deviating from the scope and spirit of the invention. The design structure of the invention is not limited to any specific design flow.

Ultimately, design process 910 preferably translates circuit 100, along with the rest of the integrated circuit design (if applicable), into a final design structure 990 (e.g., information stored in a GDS storage medium). Final design structure 990 may comprise information such as, for example, test data files, design content files, manufacturing data, layout parameters, wires, levels of metal, vias, shapes, test data, data for routing through the manufacturing line, and any other data required by a semiconductor manufacturer to produce circuit 100. Final design structure 990 may then proceed to a stage 995 where, for example, final design structure 990: proceeds to tape-out, is released to manufacturing, is sent to another design house or is sent back to the customer.

While particular embodiments of the present invention have been described herein for purposes of illustration, many modifications and changes will become apparent to those skilled in the art. Accordingly, the appended claims are intended to encompass all such modifications and changes as fall within the true spirit and scope of this invention.

1. A design structure embodied in a machine readable medium used in a design process, the design structure comprising:
(a) a first differential comparator circuit,
wherein the first differential comparator circuit receives as input (i) a first differential clock signal and (ii) a reference voltage, and generates a first output signal;
(b) a second differential comparator circuit,
wherein the second differential comparator circuit receives as input (i) the first differential clock signal and (ii) a second differential clock signal, and generates a second output signal,
wherein in response to the first and the second differential clock signals switching, the second differential comparator circuit is capable of causing the second output signal to switch logic states;
(c) a third differential comparator circuit,
wherein the third differential comparator circuit receives as input (i) the reference voltage and (ii) the second differential clock signal, and generates a third output signal;
(d) a bus change-over detecting circuit,
wherein the bus change-over detecting circuit receives as input (i) the first output signal, and (ii) the third output signal, and generates an Enable signal; and
(e) a latch circuit,
wherein the latch circuit receives as input (i) the second output signal, and (ii) the Enable signal,
wherein the latch circuit generates a digital clock signal, and
wherein the latch circuit comprises a latch, and
wherein in response to a high-high condition that both the first and second differential clock signals are higher than the reference voltage becoming true, the latch circuit is configured to hold the digital clock signal at a previous state which was generated by the latch circuit immediately before the high-high condition becomes true.

2. The design structure of claim 1,
wherein the bus change-over detecting circuit comprises a NAND gate.

3. The design structure of claim 1,
wherein in response to the first and second differential clock signals not being both higher than the reference voltage, the bus change-over detecting circuit is capable of adjusting the Enable signal resulting in the second output signal passing unchanged through the latch circuit as the digital clock signal.

4. The design structure of claim 1, wherein the design structure comprises a netlist, which describes the circuit.

5. The design structure of claim 1, wherein the design structure resides on a GDS storage medium.

6. The design structure of claim 1, wherein the design structure includes at least one item selected from the group consisting of test data files, characterization data, verification data, and design specifications.

7. A design structure embodied in a machine readable medium used in a design process, the design structure comprising:
(a) a first differential comparator circuit,
wherein the first differential comparator circuit receives as input (i) a first differential clock signal and (ii) a reference voltage, and generates a first output signal;
(b) a second differential comparator circuit,
wherein the second differential comparator circuit receives as input (i) the first differential clock signal and (ii) a second differential clock signal, and generates a second output signal,
wherein in response to the first and the second differential clock signals switching, the second differential comparator circuit is capable of causing the second output signal to switch logic states;
(c) a third differential comparator circuit,
wherein the third differential comparator circuit receives as input (i) the reference voltage and (ii) the second differential clock signal, and generates a third output signal;
(d) a bus change-over detecting circuit,
wherein the bus change-over detecting circuit receives as input (i) the first output signal, and (ii) the third output signal, and generates an Enable signal; and
(e) a latch circuit,
wherein the latch circuit receives as input (i) the second output signal, and (ii) the Enable signal,
wherein the latch circuit generates a digital clock signal,
wherein the latch circuit comprises a latch,
wherein the latch comprises a first inverter and a second inverter,
wherein the first inverter and the second inverter are cross coupled,
wherein the second inverter comprises a Glitch Immunity circuit, and
wherein the first inverter generates a fourth output signal.

8. The design structure of claim 7,
wherein the latch circuit further comprises a third inverter and a fourth inverter coupled in series,
wherein the third inverter receives as input the second output signal, and generates the fourth output signal,
wherein the fourth inverter receives as input the fourth output signal, and generates the digital clock signal, and
wherein the latch receives as input the fourth output signal.

9. The design structure of claim 7, wherein the design structure comprises a netlist, which describes the circuit.

10. The design structure of claim 7, wherein the design structure resides on a GDS storage medium.

11. The design structure of claim 7, wherein the design structure includes at least one item selected from the group consisting of test data files, characterization data, verification data, and design specifications.

12. A design structure embodied in a machine readable medium used in a design process, the design structure comprising:
(a) a first differential comparator circuit,
wherein the first differential comparator circuit receives as input (i) a first differential clock signal and (ii) a reference voltage, and generates a first output signal;
(b) a second differential comparator circuit,
wherein the second differential comparator circuit receives as input (i) the first differential clock signal and (ii) a second differential clock signal, and generates a second output signal,
wherein in response to the first and the second differential clock signals switching, the second differential comparator circuit is capable of causing the second output signal to switch logic states;
(c) a third differential comparator circuit,
wherein the third differential comparator circuit receives as input (i) the reference voltage and (ii) the second differential clock signal, and generates a third output signal;
(d) a bus change-over detecting circuit,
wherein the bus change-over detecting circuit receives as input (i) the first output signal, and (ii) the third output signal, and generates an Enable signal; and
(e) a latch circuit,
wherein the latch circuit receives as input (i) the second output signal, and (ii) the Enable signal,
wherein the latch circuit generates a digital clock signal,
wherein the latch circuit comprises a latch,
wherein the latch circuit further comprises a third inverter and a fourth inverter coupled in series,
wherein the third inverter receives as input the second output signal, and generates a fifth output signal,
wherein the fourth inverter receives as input the fifth output signal, and generates the digital clock signal, and
wherein the latch receives as input the fifth output signal.

13. The design structure of claim 12,
wherein the latch circuit further comprises a fifth inverter,
wherein the fifth inverter receives as input the Enable signal, and
wherein the fifth inverter comprises an output node electrically coupled to the third inverter.

14. A design structure embodied in a machine readable medium used in a design process, the design structure comprising:
(a) a first differential comparator circuit,
wherein the first differential comparator circuit receives as input (i) a first differential clock signal and (ii) a reference voltage, and generates a first output signal;
(b) a second differential comparator circuit,
wherein the second differential comparator circuit receives as input (i) the first differential clock signal and (ii) a second differential clock signal, and generates a second output signal,
wherein in response to the first and the second differential clock signals switching, the second differential comparator circuit is capable of causing the second output signal to switch logic states;
(c) a third differential comparator circuit,
wherein the third differential comparator circuit receives as input (i) the reference voltage and (ii) the second differential clock signal, and generates a third output signal;
(d) a bus change-over detecting circuit,
wherein the bus change-over detecting circuit receives as input (i) the first output signal, and (ii) the third output signal, and generates an Enable signal; and
(e) a latch circuit,
wherein the latch circuit receives as input (i) the second output signal, and (ii) the Enable signal,
wherein the latch circuit generates a digital clock signal, and
wherein the latch circuit comprises a latch,
wherein in response to the first and second differential clock signals not being both higher than the reference voltage, the bus change-over detecting circuit is capable of adjusting the Enable signal resulting in the second output signal passing unchanged through the latch circuit as the digital clock signal, and
wherein in response to both the first and second differential clock signals being higher than the reference voltage, the latch circuit is capable of holding the digital clock signal at a previous state.

15. The design structure of claim 14,
wherein the bus change-over detecting circuit comprises a NAND gate,
wherein the latch comprises a first inverter and a second inverter,
wherein the first inverter and the second inverter are cross coupled,
wherein the second inverter comprises a Glitch Immunity circuit, and
wherein the first inverter generates a fourth output signal.

16. The design structure of claim 14,
wherein the latch circuit further comprises a third inverter and a fourth inverter coupled in series,
wherein the third inverter receives as input the second output signal, and generates a fifth output signal,
wherein the fourth inverter receives as input the fifth output signal, and generates the digital clock signal,
wherein the latch receives as input the fifth output signal,
wherein the latch circuit further comprises a fifth inverter,
wherein the fifth inverter receives as input the Enable signal, and
wherein the fifth inverter comprises an output node electrically coupled to the third inverter.

17. The design structure of claim 14,
wherein the latch circuit further comprises a third inverter and a fourth inverter coupled in series,
wherein the third inverter receives as input the second output signal, and generates the fifth output signal,
wherein the fourth inverter receives as input the fifth output signal, and generates the digital clock signal,
wherein the latch receives as input the fifth output signal,
wherein the latch circuit further comprises a third inverter and a fourth inverter coupled in series,
wherein the third inverter receives as input the second output signal, and generates the fourth output signal,
wherein the fourth inverter receives as input the fourth output signal, and generates the digital clock signal, and
wherein the latch receives as input the fourth output signal.

18. The design structure of claim 14, wherein the design structure comprises a netlist, which describes the circuit.

19. The design structure of claim 14, wherein the design structure resides on a GDS storage medium.

20. The design structure of claim 14, wherein the design structure includes at least one item selected from the group consisting of test data files, characterization data, verification data, and design specifications.
